(19) United States
(12) Patent Application Publication
(10) Pub. No.: US 2026/0202736 A1
(43) Pub. Date: Jul. 16, 2026

(54) PELLICLE STRUCTURE FOR EUV LITHOGRAPHY AND METHODS OF MANUFACTURING THEREOF

(71) Applicant: Taiwan Semiconductor Manufacturing Company, Ltd., Hsinchu (TW)

(72) Inventors: Yen-Chi CHEN, Hsinchu (TW); Ting-Pi SUN, Hsinchu (TW); Dung-Yue SU, Hsinchu (TW); Cheng Hao JHANG, Hsinchu (TW); Huan-Ling LEE, Hsinchu (TW); Ming-Hsing TSAI, Hsinchu (TW)

(73) Assignee: Taiwan Semiconductor Manufacturing Company, Ltd., Hsinchu (TW)

(21) Appl. No.: 19/232,379

(22) Filed: Jun. 9, 2025

Related U.S. Application Data
(60) Provisional application No. 63/744,998, filed on Jan. 14, 2025.

(51) Int. Cl. G03F 1/62; C01B 32/168

(52) U.S. Cl. CPC G03F 1/62; C01B 32/168

(57) ABSTRACT

A method of manufacturing a pellicle includes heating a membrane including a plurality of carbon nanotubes at a temperature sufficient to convert amorphous carbon to crystalline carbon. The membrane is heated in a chamber having an oxygen content less than air. A pellicle is formed using the membrane after the heating the membrane. In an embodiment, the membrane includes a plurality of carbon shells having a first level of crystallinity, and during the heating the membrane, the plurality of carbon shells having the first level of crystallinity are converted to a plurality of carbon shells having a second level of crystallinity, where the second level of crystallinity is greater than the first level of crystallinity. In an embodiment, the membrane includes a metal catalyst at a first concentration, and during the heating the membrane, the first concentration of the metal catalyst decreases to a second concentration.

### RELATED APPLICATIONS

This application claims priority of U.S. Provisional Patent Application No. 63/744,998 filed Jan. 14, 2025, the entire content of which is incorporated herein by reference.

### BACKGROUND

A pellicle is a thin transparent film stretched over a frame that is glued over a photomask to protect the photomask from damage, dust and/or moisture. In extreme ultraviolet (EUV) lithography, a pellicle having a high transparency in the EUV wavelength region, a high mechanical strength and a low or no contamination is generally applied.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B show nanotubes and pellicles for an EUV photomask in accordance with embodiments of the present disclosure.

FIGS. 2A, 2B, 2C, and 2D show various views of multiwall nanotubes in accordance with embodiments of the present disclosure.

FIGS. 3A, 3B, and 3C show process stages for manufacturing a pellicle for an EUV photomask in accordance with an embodiment of the present disclosure.

FIG. 4 shows a process stage for manufacturing a pellicle for an EUV photomask in accordance with an embodiment of the present disclosure.

FIGS. 5A and 5B show a cross sectional view and a plan (top) view of one of the various stages for manufacturing a pellicle for an EUV photomask in accordance with an embodiment of the present disclosure.

FIGS. 6A and 6B show a cross sectional view and a plan (top) view of one of the various stages for manufacturing a pellicle for an EUV photomask in accordance with an embodiment of the present disclosure.

FIGS. 7A, 7B, 7C, 7D, and 7E show a process flow for various stages for manufacturing a pellicle for an EUV photomask in accordance with embodiments of the present disclosure.

FIGS. 8A, 8B, 8C, and 8D show a process flow for various stages for manufacturing a pellicle for an EUV photomask in accordance with embodiments of the present disclosure.

FIGS. 9A, 9B, 9C, and 9D show process stages for manufacturing a pellicle for an EUV photomask in accordance with an embodiment of the present disclosure.

FIGS. 10A, 10B, 10C, 10D, 10E, and 10F show process stages of forming crystalline hollow carbon shells in accordance with an embodiment of the present disclosure.

FIGS. 11A, 11B, and 11C show process stages for manufacturing a pellicle for an EUV photomask in accordance with an embodiment of the present disclosure.

FIGS. 12A, 12B, 12C, and 12D show process stages for manufacturing a pellicle for an EUV photomask in accordance with embodiments of the present disclosure.

FIG. 13 shows a process stage for manufacturing a pellicle for an EUV photomask in accordance with embodiments of the disclosure.

FIG. 14 shows a flowchart of a method of manufacturing a pellicle for an EUV photomask in accordance with an embodiment of the present disclosure.

FIG. 15 shows a flowchart of a method of manufacturing a pellicle for an EUV photomask in accordance with an embodiment of the present disclosure.

FIG. 16 shows a flowchart of a method of manufacturing a pellicle for an EUV photomask in accordance with an embodiment of the present disclosure.

FIG. 17A shows a flowchart of a method making a semiconductor device, and FIGS. 17B, 17C, 17D, and 17E show a sequential manufacturing operation of a method of manufacturing a semiconductor device according to embodiments of present disclosure.

### DETAILED DESCRIPTION

It is to be understood that the following disclosure provides many different embodiments, or examples, for implementing different features of the invention. Specific embodiments or examples of components and arrangements are described below to simplify the present disclosure. These are, of course, merely examples and are not intended to be limiting. For example, dimensions of elements are not limited to the disclosed range or values, but may depend upon process conditions and/or desired properties of the device. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact. Various features may be arbitrarily drawn in different scales for simplicity and clarity. In the accompanying drawings, some layers/features may be omitted for simplification.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. In addition, the term “made of” may mean either “comprising” or “consisting of.” Further, in the following fabrication process, there may be one or more additional operations in between the described operations, and the order of operations may be changed. In the present disclosure, the phrase “at least one of A, B and C” means either one of A, B, C, A+B, A+C, B+C or A+B+C, and does not mean one from A, one from B and one from C, unless otherwise explained. Materials, configurations, structures, operations and/or dimensions explained with one embodiment can be applied to other embodiments, and detained description thereof may be omitted.

EUV lithography is one of the crucial techniques for extending Moore's law. However, due to wavelength scaling from 193 nm (ArF) to 13.5 nm, the EUV light source suffers from strong power decay due to environmental adsorption. Even though a stepper/scanner chamber is operated under vacuum to prevent strong EUV adsorption by gas, maintaining a high EUV transmittance from the EUV light source to a wafer is still an important factor in EUV lithography.

A pellicle generally requires a high transparency and a low reflectivity. In ultraviolet (UV) or deep UV (DUV) lithography, the pellicle film is made of a transparent resin film. In EUV lithography, however, a resin-based film would not be acceptable, and a non-organic material, such as a polysilicon, silicide, or metal film, is used in some embodiments.

One of the EUV production performance bottlenecks is EUV mask pellicle failure, such as distortion, cracking, and breaking.

Carbon nanotubes (CNTs) are one of the materials suitable for a pellicle for an EUV photomask because CNTs have a high EUV transmittance of more than 96.5%. Generally, a pellicle for an EUV reflective mask requires the following properties: (1) Long life-time in a hydrogen radical rich operation environment in an EUV stepper/scanner; (2) Strong mechanical strength to minimize the sagging effect during vacuum pumping and venting operations; (3) A high or perfect blocking property for particles larger than about 20 nm (killer particles); and (4) Good heat dissipation to prevent the pellicle from being burnt out by EUV radiation.

However, the strong CNT sp2 bond can easily be etched in the EUV scanner environment by EUV-induced hydrogen and oxygen plasma. Protective coatings for CNT include amorphous films. However, the amorphous films can also easily be etched in the EUV scanner environment, which lowers the usefulness of the protective coating. CNT non-uniformity may also be a problem. The non-uniformity may result in poor pattern imaging by poor EUVT (EUV transmittance) and/or poor EUVR (EUV reflectivity).

In addition, the pellicle temperature increases with increasing EUV power. For example, the temperature of the pellicle may be in the range of 527±50° C. when the EUV power is 436±20 W. Some CNT pellicles may not be able to withstand such high temperatures, since they are only thermally stable up to a range of about 500° C. to about 700° C.

In this disclosure, a method that provides high transmittance, high strength EUV pellicles, with higher chemical stability is disclosed. According to some embodiments of the present disclosure, the transmittance, strength, and chemical resistance of the pellicles are improved by increasing the crystallinity of pellicle membrane. In some embodiments of the disclosure, a pellicle membrane 100 is made of a plurality of CNTs 20b and a plurality of carbon shells 25b. In other embodiments, the pellicle membrane is made of a plurality of CNTs 20b. The crystallinity of the CNTs and carbon shells is increased by subjecting the CNTs and shells to a high temperature treatment. The high temperature treatment converts or transforms amorphous portions of the CNTs and carbon shells to crystalline portions. In some embodiments, the crystalline portions are graphite or graphene.

In some embodiments of the present disclosure, a nanotube is an elongated tube having a diameter in a range from about 0.5 nm to about 100 nm.

In some embodiments of the present disclosure, a pellicle for an EUV photomask includes a network membrane having a plurality of nanotubes and hollow shells that form a mesh structure. Further, a method of producing the pellicle having increased mechanical strength, chemical resistance, and increased EUV transmittance is also disclosed.

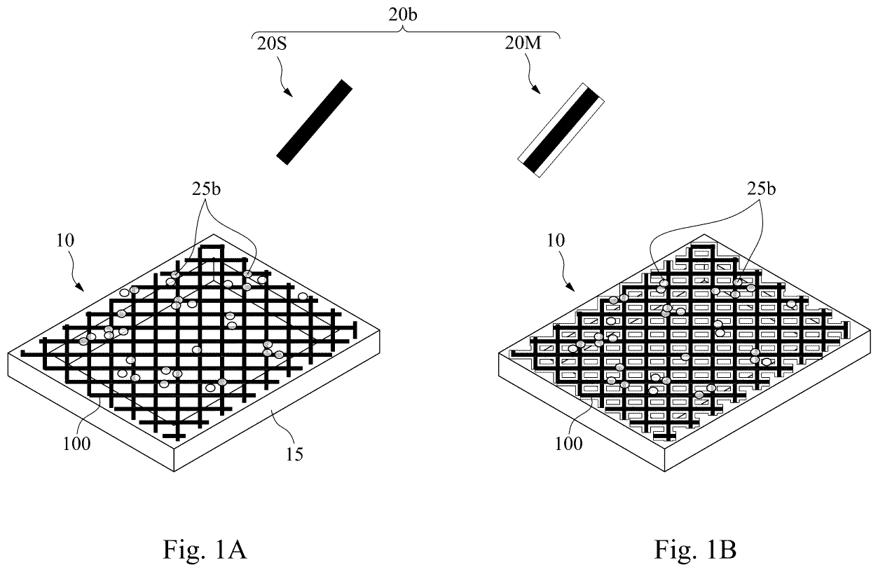

FIGS. 1A and 1B show EUV pellicles 10 in accordance with an embodiment of the present disclosure. In some embodiments, a pellicle 10 for an EUV reflective mask includes a main network membrane 100 disposed over and attached to a pellicle frame 15. In some embodiments, the main network membrane 100 is a transparent membrane transparent to electromagnetic radiation, such as EUV radiation. In some embodiments, the transparent membrane 100 has an EUV transmittance of more than 96.5%. The transparent membrane 100 may be opaque to some electromagnetic wavelengths, such as infrared or visible radiation and transparent to other electromagnetic wavelengths, such as EUV radiation or X-ray radiation. In some embodiments, as shown in FIG. 1A, the main network membrane 100 includes a plurality of nanotubes 20b, such as single wall nanotubes 20S, and a plurality of hollow carbon shells 25b. In other embodiments, as shown in FIG. 1B, the nanotubes 20b making up the main network membrane 100 includes a plurality of multiwall nanotubes 20M. In some embodiments, the nanotubes bond or attach to each other to form a bundle of nanotubes. In some embodiments, the main network membrane 100 is mostly made up of CNTs 20b. In some embodiments, the main network membrane 100 is made up of over 90% CNTs 20b by weight and less than 10% carbon shells 25b by weight. In some embodiments, the main network membrane 100 is made up of over 95% CNTs 20b by weight and less than 5% carbon shells 25b by weight, and in other embodiments, the main network membrane 100 is made up of over 99% CNTs 20b by weight and less than 1% carbon shells 25b by weight. Thus, in some embodiments, the main network membrane 100 is substantially free of carbon shells 25b.

In some embodiments, a multiwall nanotube is a coaxial nanotube having one or more walls coaxially surrounding an inner tube(s). In some embodiments, the main network membrane 100 includes only one type of nanotube (e.g.-single wall or multiwall or single material) and in other embodiments, different types of nanotubes form the main network membrane 100. In some embodiments, some of the multiwall nanotubes form a bundle of nanotubes attached to each other.

In some embodiments, a pellicle (support) frame or border 15 is attached to the main network membrane 100 to maintain a space between the main network membrane of the pellicle and an EUV mask (pattern area) when mounted on the EUV mask. The pellicle frame 15 of the pellicle is attached to the surface of the EUV photomask with an appropriate bonding material. In some embodiments, the bonding material is an adhesive, such as an acrylic or silicon-based glue or a cross link type adhesive. The size of the frame structure is larger than the area of the black borders of the EUV photomask so that the pellicle covers not only the circuit pattern area of the photomask but also the black borders.

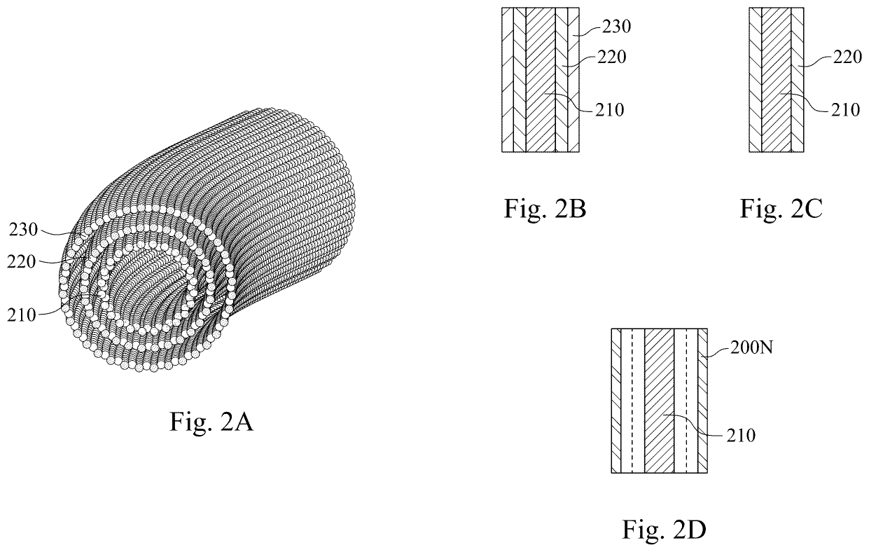

FIGS. 2A, 2B, 2C, and 2D show various views of multiwall nanotubes in accordance with embodiments of the present disclosure.

In some embodiments, the nanotubes in the main network membrane 100 include multiwall nanotubes, which are also referred to as coaxial nanotubes. FIG. 2A shows a perspective view of a multiwall coaxial nanotube having three tubes 210, 220, and 230 and FIG. 2B shows a cross sectional view thereof.

The number of tubes of the multiwall nanotubes is not limited to three. In some embodiments, the multiwall nanotube has two coaxial nanotubes as shown in FIG. 2C, and in other embodiments, the multiwall nanotube includes the innermost tube 210 and the first to N-th nanotubes including the outermost tube 200N, where N is a natural number from 1 to about 30, as shown in FIG. 2D. In some embodiments, N ranges from 3 to 20, and 5 to 10 in other embodiments. In some embodiments, at least one of the first to the N-th outer layers is a nanotube coaxially surrounding the innermost nanotube 210.

In some embodiments, a diameter of the innermost nanotube ranges from about 0.5 nm to about 20 nm, ranges from about 1 nm to about 10 nm in other embodiments, and ranges from about 2 nm to about 5 nm in other embodiments. In some embodiments, a diameter of the multiwall nanotubes (i.e., diameter of the outermost tube) ranges from about 3 nm to about 40 nm and ranges from about 5 nm to about 20 nm in other embodiments. In some embodiments, a length of the multiwall nanotube ranges from about 0.5 μm to about 50 μm and ranges from about 1.0 μm to about 20 μm in other embodiments.

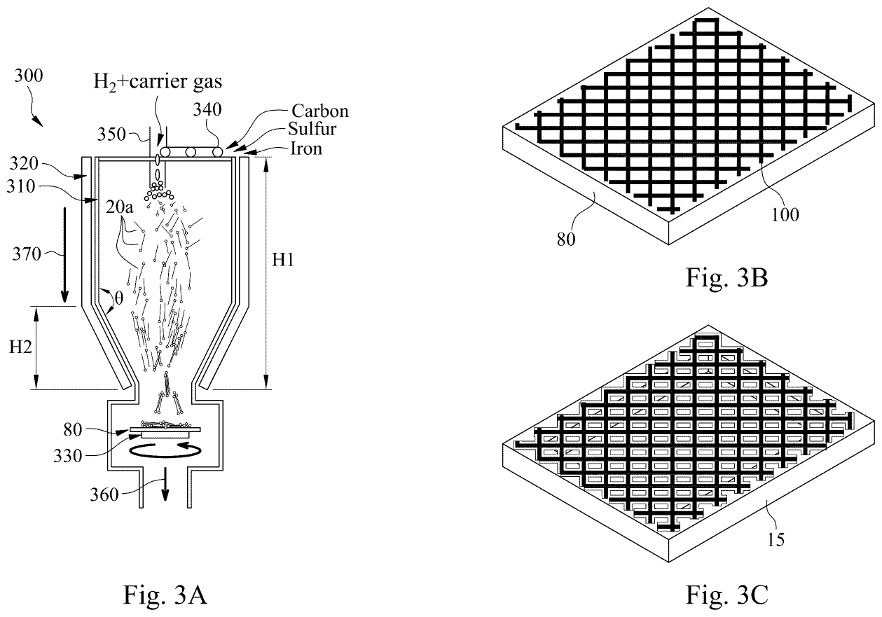

FIGS. 3A, 3B, and 3C show a manufacturing method of nanotube network membranes for a pellicle in accordance with embodiments of the present disclosure.

In some embodiments, carbon nanotubes (CNTs) 20a are formed by a chemical vapor deposition (CVD) process. In some embodiments, a CVD process is performed by using a vertical furnace as shown in FIG. 3A, and synthesized nanotubes are deposited on a support membrane 80 as shown in FIG. 3B. Then, the network membrane 100 formed over the support membrane 80 is detached from the support membrane 80, and transferred on to the pellicle frame 15 as shown in FIG. 3C.

In an embodiment illustrated in FIG. 3A, floating catalyst CVD process is used to form carbon nanotubes (CNTs). A funnel quartz design reactor 300 is used to form CNTs 20a in some embodiments. The reactor 300 includes tubular quartz walls 310. An upper portion of the quartz tube is cylindrical shape and a lower portion is cone shaped. The quartz tube walls are surrounded by a heater 320. The nanotubes 20a are deposited on a filter or support membrane 80. In some embodiments, a stage or mask 330, on which the support membrane 80 is disposed, rotates continuously or intermittently (step-by-step manner) so that the synthesized nanotubes are deposited on the support membrane 80 with different or random directions. In some embodiments, the membrane support is a filter paper. In some embodiments, the mask 330 is a plate that inhibits the CNTs 20a from penetrating the support membrane 80. The CNTs 20a can penetrate the filter in the unmasked regions of the support membrane 80 in some embodiments.

In some embodiments, the funnel quartz design reactor has a tube diameter ranging from about 1 cm to about 100 cm in the upper cylindrical portion tapering to a diameter ranging from about 1 mm to about 10 cm at the end of the lower cone portion. The reactor has a height H1 ranging from about 200 cm to about 600 cm and the tapered portion of the lower cone portion has a height H2 ranging from about 10 cm to about 100 cm in some embodiments. A taper angle θ of the lower cone portion ranges from about 80° to about 160° in some embodiments.

To produce the CNTs 20a, a carbon source is introduced into a reactor inlet 340 along with a catalyst. In some embodiments, a sulfur compound is also introduced into the reactor inlet 340. In some embodiments, the carbon source includes one or more hydrocarbon gases, including methane at a flow rate ranging from greater than 0 sccm to about 800 sccm, and ethane at a flow rate ranging from greater than 0 sccm to about 900 sccm. In some embodiments, the carbon source is introduced at a flow rate ranging from about 4 sccm to about 200 sccm. In some embodiments, the catalyst may be any suitable catalyst, such as iron or an iron-containing catalyst, including ferrocene (Fe(C₅H₅)₂), and transition metal carbonyl complexes, including M(CO)ₓ where M is a transition metal, such as Cr, Mo, or W, and x ranges from 3 to 10 in some embodiments. Other suitable catalysts include one or more of CoFe, Co, CoNi, Ni, CoMo, and FeMo. In some embodiments, the catalyst is introduced into the reactor at a flow rate ranging from greater than 0 sccm to about 1 sccm. In some embodiments, a sulfur containing compound is introduced into the reactor. The sulfur containing compound is one or more of hydrogen sulfide and thiophene. The sulfur containing compound is introduced into the reactor at a flow rate ranging from greater than 0 sccm to about 1 sccm. In some embodiments, hydrogen and a carrier gas are introduced into the reactor in a gas inlet 350. The carrier gas can include one or more of argon, nitrogen, and oxygen. The hydrogen can be introduced into the reactor at a flow rate ranging from greater than 0 sccm to about 1000 sccm. The carrier gases may be introduced into the reactor at the following flow rates: argon-about 0 to about 50,000 sccm, nitrogen about 0 sccm to about 60,000 sccm, and oxygen about 0 to about 1 sccm.

The reactor is heated to a temperature ranging from about 300° C. to about 1100° C. during the CNT growth operation in some embodiments. In some embodiments, a temperature gradient 370 is maintained along the height of the reactor. For example, in some embodiments, the temperature increases from the top of the reactor towards the bottom of the reactor or vice versa. In some embodiments, the temperature along the gradient increases from about 300° C. to about 1100° C. The mask or stage 330 is rotated at a rate of about 0 rpm to about 500 rpm in some embodiments. A vacuum 360 is pulled during nanotube growth operation to provide a uniform CNT dispersion in some embodiments. In some embodiments, the growth operation is continued for a sufficient period of time to obtain a desired thickness of the nanotube network layer.

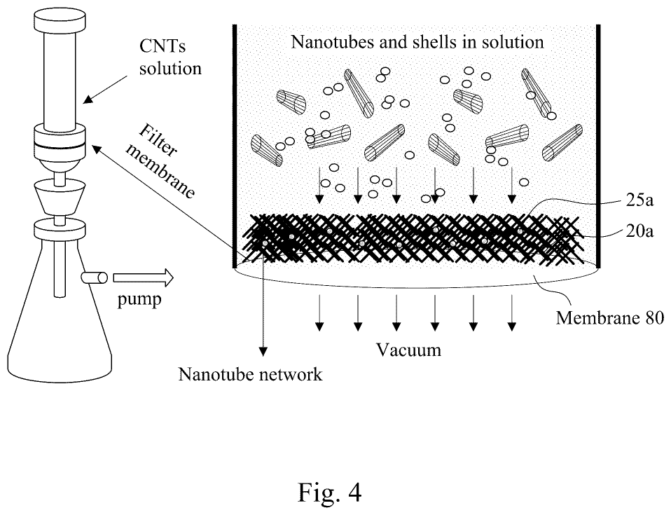

FIG. 4 shows another method of manufacturing a network membrane of nanotubes in accordance with an embodiment of the present disclosure. In some embodiments, the nanotubes are formed by various other methods, such as CVD, arc-discharge, or laser ablation methods, and the hollow carbon shells are formed by laser ablation, hydrothermal carbonization, electrochemical dealloying, co-electrolysis, or a carbonation process. The nanotubes and carbon shells are then dispersed in a solution. In some embodiments, the solution includes a solvent, such as water or an organic solvent, and a surfactant, such as sodium dodecyl sulfate (SDS).

As shown in FIG. 4, a support membrane or filter 80 is placed between a chamber or a cylinder in which the nanotubes and carbon shells dispersed solution is disposed and a vacuum chamber. In some embodiments, the support membrane is an organic or inorganic porous or mesh material. In some embodiments, the support membrane is a woven or non-woven fabric. In some embodiments, the support membrane has a circular shape in which a pellicle size of a 150 mm ×150 mm square (the size of an EUV mask) can be placed.

As shown in FIG. 4, the pressure in the vacuum chamber is reduced so that a pressure is applied to the solvent in the chamber or cylinder. Since the mesh or pore size of the support membrane or filter is sufficiently smaller than the size of the nanotubes and carbon shells, the nanotubes 20a and carbon shells 25a are captured by the support membrane while the solvent passes through the support membrane. The support membrane on which the nanotubes are deposited is detached from the filtration apparatus and dried. In some embodiments, the deposition by filtration is repeated to obtain a desired thickness of the nanotube network layer. In some embodiments, after the deposition of the nanotubes and shells in the solution, other nanotubes and shells are dispersed in the same or new solution and the filter-deposition is repeated. In other embodiments, after the nanotubes and shells are dried, another filter-deposition is performed. In the repetition, the same type of nanotubes and shells are used in some embodiments, and different types of nanotubes are used in other embodiments. In some embodiments, the nanotubes dispersed in the solution include multiwall nanotubes.

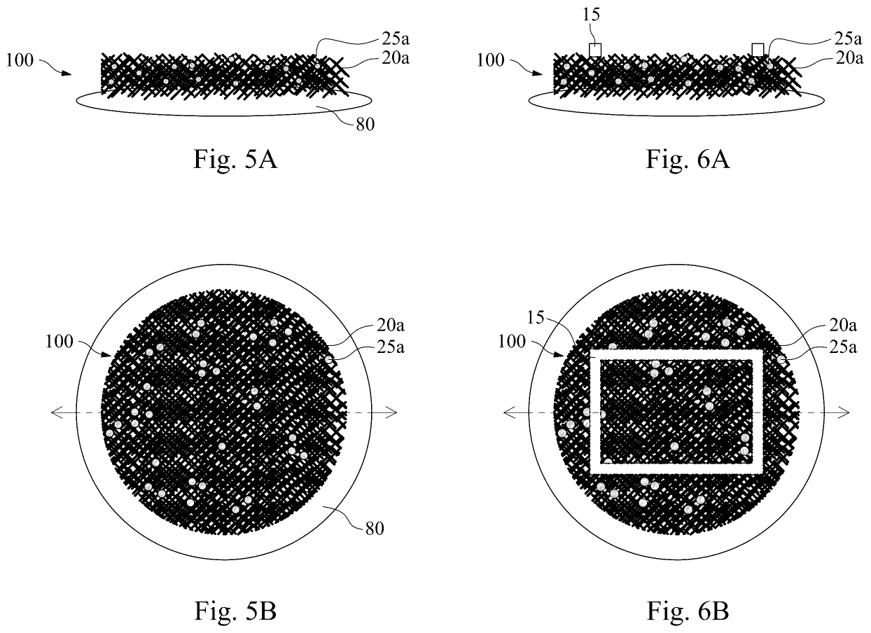

FIGS. 5A and 5B and 6A and 6B show cross sectional views (the “A” figures) and plan (top) views (the “B” figures) of the various stages for manufacturing a pellicle for an EUV photomask in accordance with an embodiment of the present disclosure. It is understood that additional operations can be provided before, during, and after the processes shown by FIGS. 5A-6B, and some of the operations described below can be replaced or eliminated, for additional embodiments of the method. The order of the operations/processes may be interchangeable. Materials, configurations, methods, processes and/or dimensions as explained with respect to the foregoing embodiments are applicable to the following embodiments, and the detailed description thereof may be omitted.

As shown in FIGS. 5A and 5B, a layer of CNTs 20a and carbon shells 25a are formed on a support membrane 80 by one or more methods as explained above. In some embodiments, the nanotubes 20 include single wall nanotubes, multiwall nanotubes, or mixtures thereof. In some embodiments, the nanotubes 20a include single wall nanotubes only.

Then, as shown in FIGS. 6A and 6B, a pellicle frame or border 15 is attached to the layer of carbon nanotubes 20a and carbon shells 25a in some embodiments. In some embodiments, the pellicle frame 15 is formed of one or more layers of a crystalline silicon, a polysilicon, a silicon oxide, a silicon nitride, silicon carbide, aluminum oxide, zirconium dioxide, tantalum nitride, niobium nitride, or a ceramic material. In some embodiments, the pellicle frame 15 is formed of one or more layers of graphite or an ultra-high temperature ceramic, including HfCN, HfC, TaC, NbC, ZrC, HfN, HfB₂, ZrB₂, TiB₂, TiC, NbB₂, TaB₂, TiN, or ZrN. In some embodiments, as shown in FIG. 6B, the pellicle frame 15 has a rectangular (including square) frame shape, which is larger than the black border area of an EUV mask and smaller than the substrate of the EUV mask. In some embodiments, the pellicle frame is attached to the nanotube layer by a cold welding operation.

The layer of nanotubes 20a and carbon shells 25a and the support membrane 80 are subsequently cut into a rectangular shape having the same size as or slightly larger than the pellicle frame 15, and then the support membrane 80 is detached or removed, in some embodiments. When the support membrane 80 is made of an organic material, the support membrane 80 is removed by wet etching using an organic solvent.

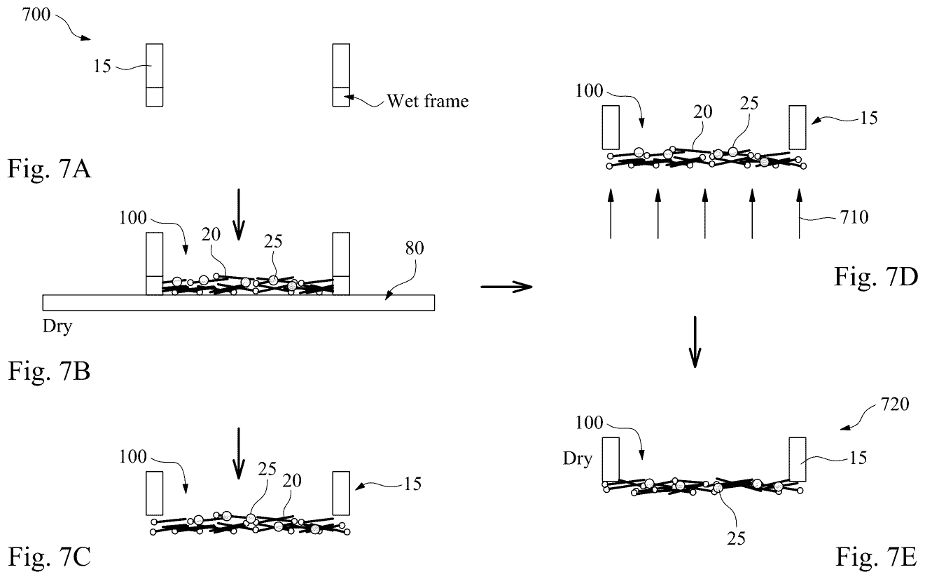

Sequential operations of a method 700 of manufacturing a pellicle according to some embodiments of the disclosure are shown in FIGS. 7A-7E. The frame 15 is initially wetted with an appropriate solvent, such as ethanol, to facilitate the attachment of the frame 15 to the main network membrane 100 of nanotubes 20a or 20b and shells 25a or 25b, as shown in FIG. 7A. The frame 15 is contacted to the main network membrane 100 and the structure is dried by air drying or vacuum drying, as shown in FIG. 7B, and then the support membrane is removed, as shown in FIG. 7C. The main network membrane 100 is treated with an appropriate solvent vapor 710, such as ethanol vapor, in FIG. 7D to densify the main network membrane in some embodiments. The solvent vapor facilitates bundling of the nanotubes in the main network membrane. During the solvent vaporing, the CNTs contact and bond to each other thereby forming CNT bundles. The pellicle structure is subsequently dried by either air drying or vacuum drying in FIG. 7E to provide a pellicle structure 720 with a membrane 100 including bundled nanotubes. In some embodiments, the solvent vaporing operation includes dipping the membrane in a higher boiling point solvent, such as isoamyl acetate, and washing and drying the network membrane 100.

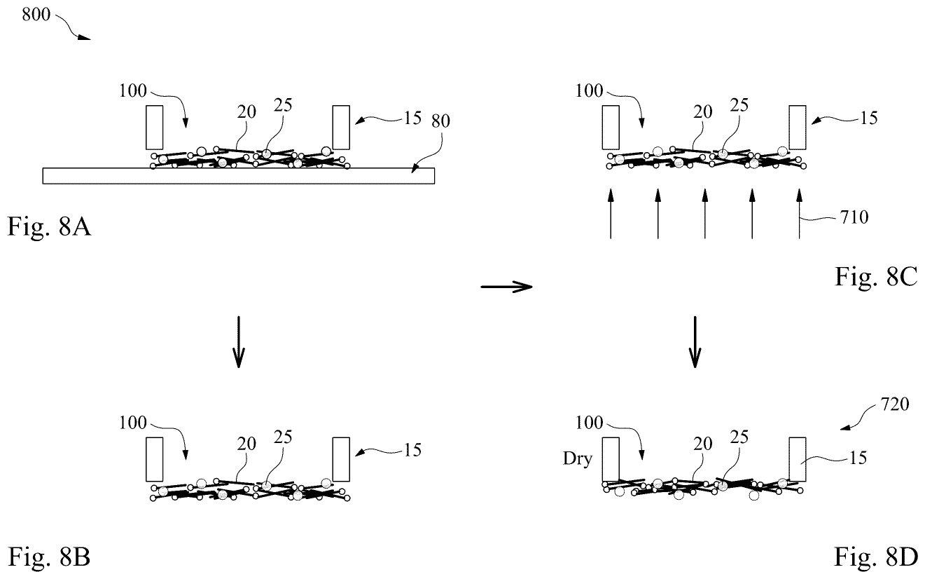

Sequential operations of another method 800 of manufacturing a pellicle according to some embodiments of the disclosure are shown in FIGS. 8A-8D. This method is similar to the method disclosed in FIGS. 7A-7E, with the exception that this method does not include the operation of wetting the frame 15 with the solvent. Thus, the operation illustrated in FIG. 8A corresponds to the operation illustrated in FIG. 7B, FIG. 8B corresponds to FIG. 7C, FIG. 8C corresponds to FIG. 7D, and the operation illustrated in FIG. 8D corresponds to FIG. 7E.

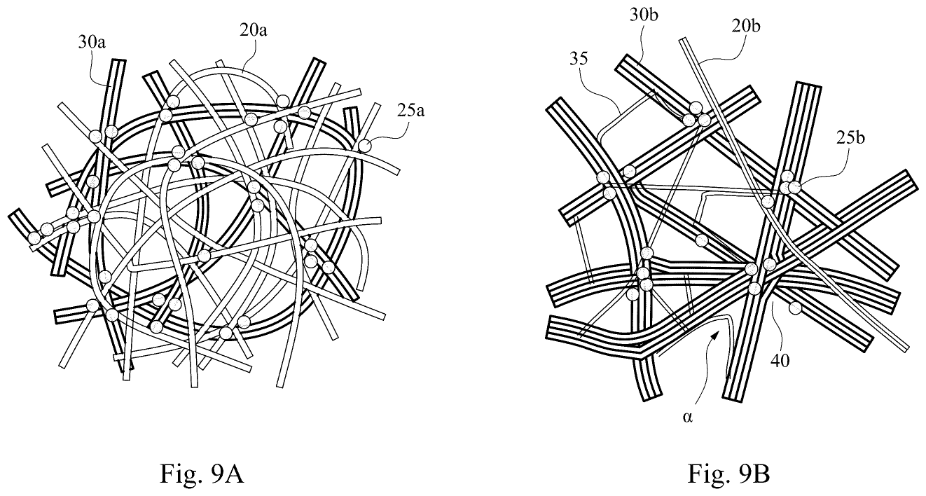

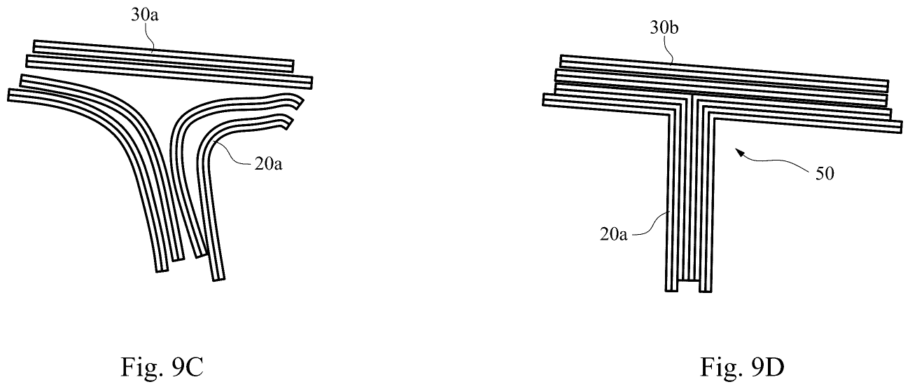

In some embodiments, the main network membrane 100 includes a combination of single nanotubes 20a, bundled nanotubes 30a, and metal catalyst particles having low crystallinity carbon shells 25a, as shown in FIG. 9A. Then the main network membrane is subjected to a heat treatment operation. In some embodiments, the temperature of the heat treatment operation is sufficient to convert or transform amorphous carbon to crystalline carbon. In some embodiments, the crystalline carbon is graphite or graphene. As a result of the heat treatment operation, the percentage of crystallinity of the carbon nanotubes and the carbon shells is increased by the heat treatment operation. In some embodiments, the membrane 100 is heated in a chamber at a temperature ranging from about 1000° C. to about 3600° C. In some embodiments, the membrane 100 is heated at a temperature ranging from about 2200° C. to about 3200° C. in a chamber having an oxygen concentration of no more than about 10 ppm during the heating. In other embodiments, the membrane is heated at a temperature ranging from about 1000° C. to about 2200° C. in a vacuum chamber at a pressure less than about 10⁻⁵ Torr during the heating, and in other embodiments, the membrane is heated at a temperature ranging from about 1500° C. to about 2000° C.

The heat treatment operation converts amorphous carbon to crystalline carbon, such as graphite or graphene, thereby increasing the crystallinity of the CNTs and the carbon shells. In some embodiments, the crystallinity of CNTs and the carbon shells is increased to greater than 70%, and in other embodiments, the crystallinity is increased to greater than 90%. The heat treatment operation also advances the carbon nanotube bundling, causing additional nanotubes to bundle together to form a larger nanotube bundle 30b having a higher crystallinity than the nanotube bundles 30a before the heat treatment operation, as shown in FIG. 9B. In some embodiments, the heat treatment operation causes different carbon nanotubes to bond to each other during the heating the membrane. In some embodiments, a bridge structure 35 made of one or more carbon nanotubes is formed between different carbon nanotubes 20b or nanotube bundles 30b during the heat treatment operation. In some embodiments, a junction structure 40 is formed between different nanotubes or nanotube bundles where they cross each other during the heat treatment operation. In some embodiments, a distinct angle α is formed in at least one CNT during the heat treatment operation. In some embodiments, at least one of the crystalline carbon nanotubes 20b is bent at angle ranging from about 10° to about 170°. In other embodiments, the angle ranges from about 30° to about 150°. In some embodiments, a carbon shell 25a with low crystallinity is converted to a crystalline polyhedral hollow particle 25b having higher crystallinity.

The formation of bridge structures 35, junction structures 40, and larger nanotube bundles 30b with increased bundling, more strongly anchors the carbon nanotubes to each other, thereby preventing the nanotubes from shifting and moving relative to each other. The improved anchoring helps the membrane 100 maintain a fixed, consistent pore size. Before the high temperature treatment operation, although CNTs 20a are intertwined, they are not significantly bonded to each other. Moreover, once subjected to the external forces, the CNTs 20a will slide against each other, causing changes in the pore sizes of the pellicle 10.

After the high temperature treatment operation, due to the metal catalyst causing the carbon atoms to rearrange and recrystallize at high temperatures, different CNTs 20b can form the bridge structures 35 between each other in some embodiments, resulting in one or more CNTs spanning across two different CNTs 20b. Furthermore, the metal catalyst particles tend to accumulate at the intersections of more than two CNTs 20a, causing the CNTs at these points to bond together after the high temperature treatment, forming junctions 40. These features help enhance the mechanical strength of the pellicle 10. Additionally, due to the significant adhesion at the junctions 40 of different CNTs 20b, the pore size of the pellicle 10 is stabilized. This prevents changes in pore size caused by the sliding of CNTs.

In some embodiments, the heat treatment causes CNTs 20a and nanotube bundles 30a, as shown in FIG. 9C, to connect to each other to form a T-shape bundle 50, as shown in FIG. 9D. The T-shape bundle 50 provides increased strength in some embodiments because the structure is bonded together in more than one direction, and there is more intimate contact between adjacent bundles 30b. The T-shape structure further prevents changes in pore size caused by the sliding of CNTs.

At heat treatment temperatures below the disclosed ranges there may be insufficient conversion of amorphous carbon to crystalline carbon, there may be insufficient removal of the metal catalyst, and insufficient formation of bridges and junctions. At heat treatment temperatures greater than the disclosed ranges there may be degradation of the membrane 100 and the process may not be economically viable because of the increased energy use to maintain the higher temperatures.

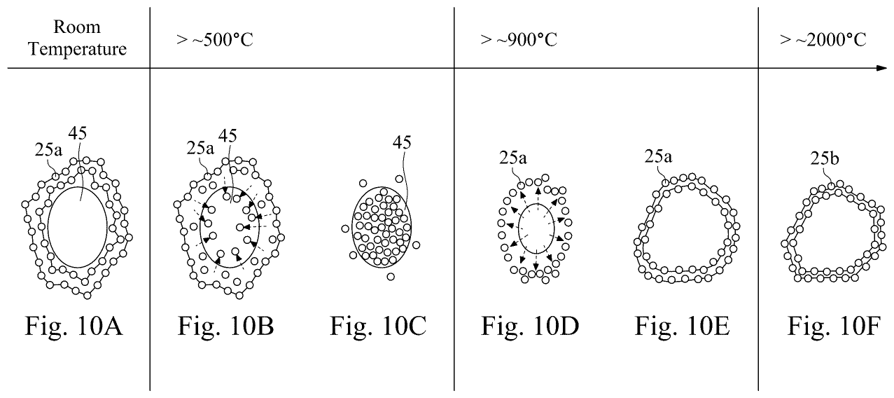

The formation of the crystalline polyhedral particle 25 will be explained in greater detail in reference to FIGS. 10A-10F. During the formation of carbon nanotubes, metal catalyst particles 45, such as iron particles, are used as sites on which nanotube growth occurs. In some embodiments, the initially formed main network membrane 100 includes a metal catalyst particle core 45, such as an iron particle, surrounded by an amorphous or low crystallinity carbon shell 25a, as shown in FIG. 10A. The core/shell may be formed by any suitable technique, including laser ablation, hydrothermal carbonization, electrochemical dealloying, co-electrolysis, or a carbonation process.

During the heat treatment operation, the temperature increases from room temperature up to about 3600° C. in some embodiments. At temperatures above about 500° C., carbon atoms dissolve into the metal particle 45 in some embodiments, as shown in FIG. 10B. The carbon atoms continue to dissolve into the metal particle 45 until the metal particle is saturated with the carbon atoms, as shown in FIG. 10C. As the temperature increases, the metal particle vaporizes. Where the metal particle is iron, the iron starts vaporizing at temperatures above about 900° C., as shown in FIG. 10D. As the metal evaporates, carbon atoms precipitate from the vaporizing metal particles. As the temperature increases, the metal catalyst particle substantially completely vaporizes and a low-crystalline or amorphous carbon shell remains, as shown in FIG. 10E. As the temperature is increased above about 2000° C., the low-crystalline or amorphous carbon shell is converted to a high-crystalline carbon shell, as shown in FIG. 10F. In some embodiments, high-crystalline carbon shells are carbon polyhedral hollow particles including many flat planes having a graphite two-dimensional structure. The low-crystalline carbon shell, on the other hand, does not have a significant amount of flat planes. In some embodiments, an angle between two adjacent flat planes ranges from about 80° to about 160°, and in other embodiments from about 100° to about 150°. The high temperature (>about 2000° C.) also removes defects in the CNTs and carbon shells. Because the metal catalyst particles are removed by the heat treatment operation, the transmittance of the membrane 100 is increased by the heat treatment operation.

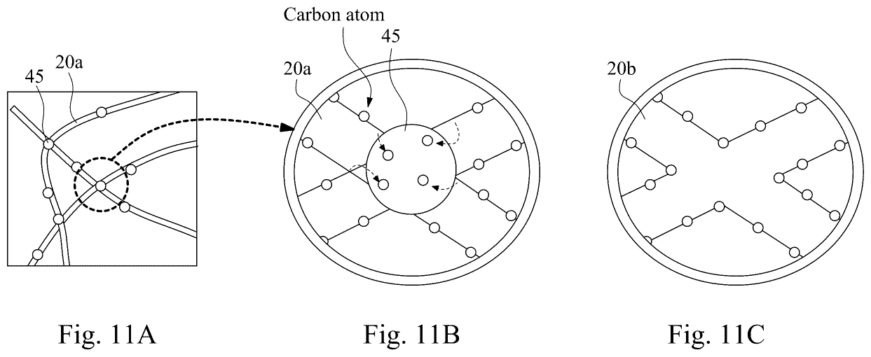

The formation of junction structures where two carbon nanotubes cross is explained in further detail in FIGS. 11A-11C. In some embodiments, CNTs merge together at their junction due to the dissolution of carbon atoms into metal particles, followed by their precipitation and recrystallization. As shown in FIG. 11A, in some embodiments, CNTs 20a cross each other at location of a metal catalyst particle 45. Furthermore, the higher temperature also results in a higher crystalline carbon structure, which improves the EUVT of the pellicle.

In some embodiments, the metal catalyst particle 45 is an iron particle. During the heat treatment operation the carbon atoms dissolve into the metal catalyst particle, as described herein and as shown in FIG. 11B. Then, as the membrane is further heated, as described herein, the carbon atoms precipitate from the vaporized metal catalyst particle. The precipitated carbon atoms merge the crossed CNTs 20b together during the crystallization process, as shown in FIG. 11C. The metal catalyst particle 45 can serve as an adhesive, bonding each CNT 20a at the junction by dissolving carbon into the metal particles and then precipitating it out at a higher temperature. This prevents changes in pore size caused by the sliding of CNTs. In addition to removing metal impurities to enhance EUV transmittance, the high-temperature treatment can further improve the exposure lifetime by enhancing the mechanical strength of the CNTs by improving the crystallinity of the carbon material. This includes the mechanical strength of the CNTs themselves, as well as the carbon precipitated from metal impurity particles at the junctions, which bond different CNTs 20b together.

In some embodiments, the heat treatment operation is performed in a vacuum or an inert gas atmosphere having an oxygen concentration of less than about 10 ppm oxygen, in other embodiments, the oxygen concentration is less than about 5 ppm, and less than about 2 ppm in yet other embodiments. In some embodiments the oxygen concentration is less than about 0.2 ppm oxygen to prevent oxidation of the CNTs and the carbon shells. In some embodiments, the oxygen concentration is less than about 0.01 ppm during the heat treatment operation, and in other embodiments, the oxygen concentration is less than about 0.001 ppm during the heat treatment operation. In some embodiments, the inert gas includes at least one of argon, neon, helium, xenon, krypton, and nitrogen. In some embodiments, the heat treatment operation is performed in a vacuum chamber at a pressure less than about 10⁻⁵ Torr. In other embodiments, the pressure in the vacuum chamber is less than about 10⁻⁷ Torr during the heat treatment operation, and in other embodiments, the pressure is less than about 10⁻⁸ Torr. At oxygen concentrations and chamber pressures greater than the disclosed ranges there may be oxidation and degradation of the main network membrane 100.

In some embodiments, after the heat treatment operation, a ratio of an intensity of the D-band to an intensity of the G-band in Raman spectroscopy (I_{D}/I_{G}) of the membrane is ≤0.1. In some embodiments, I_{D}/I_{G} is ≤0.05, and in other embodiments, I_{D}/I_{G} is ≤0.02. The ratio I_{D}/I_{G} is used to assess the structural quality and defect density of the membrane. In the Raman spectrum of carbon nanotubes, the D-band (around 1350 cm⁻¹) and the G-band (around 1580 cm⁻¹) are prominent features. The D-band is associated with disorder and defects, while the G-band represents the first-order Raman mode of a perfect graphite lattice. The ratio of the intensities of these bands (I_{D}/I_{G}) is a measure of the defect density in the carbon nanotubes. A lower I_{D}/I_{G} ratio indicates fewer defects and therefore higher structural quality.

In some embodiments, the pellicle can be coated with protection layers to prevent plasma damage during EUV exposure. By improving the crystallinity of the carbon material beforehand, the chemical stability can be increased, the impact of the coating process is reduced, providing more flexibility with coating parameters.

In some embodiments, the main network membrane 100 is heated using any suitable technique, including an electric arc furnace, induction heating, xenon flash lamps, pulsed laser heating, a graphite furnace (including a graphite electrical resistance furnace), a plasma torch, and joule heating.

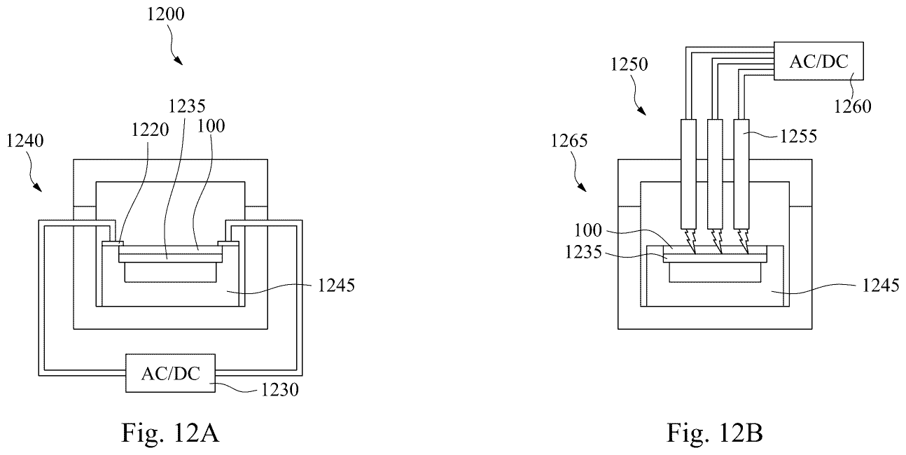

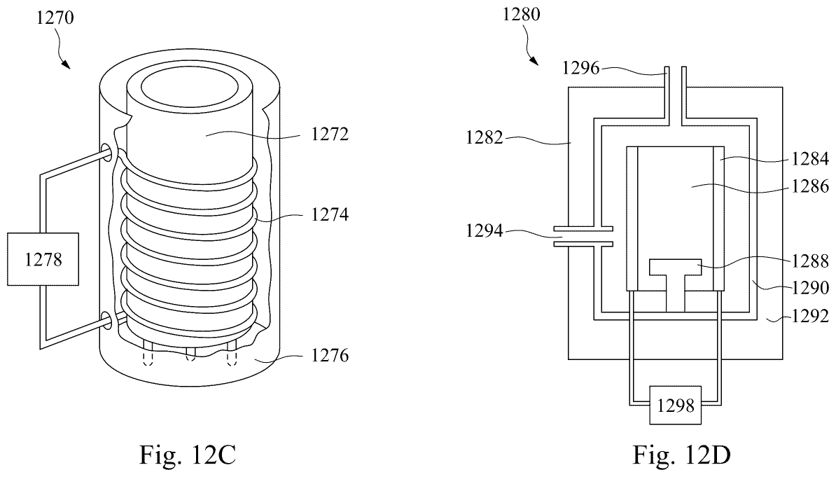

In some embodiments, joule heating is used to heat treat the main network membrane, as shown in FIG. 12A. A membrane 100 and a membrane support 1235 supporting the membrane are placed over an insulating support 1245 and are clamped at the edge portions of the membrane support 1235 by parts of the insulating support 1245 and electrodes 1220 disposed over the membrane. The insulating support 1245 is made of ceramic in some embodiments, and the electrodes 1220 are made of metal, such as tungsten, copper, or steel. The electrodes 1220 are attached to contact the membrane 100. In some embodiments, the electrodes 1220 are attached to two side portions (e.g., left and right) of the membrane 100. In some embodiments, the electrodes 1220 are connected to a current source (power supply) 1230 by wires.

As shown in FIG. 12A, a Joule heating apparatus 1200 on which the main network membrane 100 is mounted is placed in a vacuum chamber 1240. In some embodiments, the vacuum chamber 1240 includes a bottom part in which the Joule heating apparatus is placed and an upper (lid) part, and a gasket (e.g., O-ring) is disposed between the bottom part and the upper part. The wires of the Joule heating apparatus are connected to outside wires, which are connected to the power supply 1230.

In the Joule heating operation, the vacuum chamber is evacuated to a pressure equal to or lower than about 10⁻⁵ Torr in some embodiments. The power supply 1230 applies current to the membrane 100 so that the current passes through the membrane generating heat. In some embodiments, the current is DC, and in other embodiments, the current is AC or pulse current. In some embodiments, the current from the power supply 1230 is adjusted such that the membrane is heated at a temperature in a range from about 1000° C. to about 3600° C. to cause amorphous carbon in the nanotubes and shells to crystallize and/or bond to each other, as described herein.

In some embodiments, an electric arc furnace 1250 is used to perform the heat treatment operation, as shown in FIG. 12B. A membrane 100 and a membrane support 1235 supporting the membrane is placed over an insulating support 1245. A plurality of electrodes 1255 are positioned over the membrane 100. The insulating support 1245 is made of a ceramic and the electrodes 1255 are made of graphite in some embodiments. In some embodiments, the electrodes 1255 are connected to a power supply 1260 by wires.

As shown in FIG. 12B, the main network membrane 100 is placed in a vacuum chamber 1265. In the electric arc furnace operation, the vacuum chamber is evacuated to a pressure equal to or lower than about 10⁻⁵ Torr in some embodiments. The power supply 1260 applies current to the electrodes 1255 and an electric arc is ignited between the electrodes 1355 and the membrane 100 generating heat. In some embodiments, the current is DC, and in other embodiments, the current is AC or pulse current. In some embodiments, the current from the power supply 1255 is adjusted such that the membrane is heated at a temperature in a range from about 1000° C. to about 3600° C. to cause amorphous carbon in the nanotubes and shells to crystallize and/or bond to each other, as described herein.

In some embodiments, an induction furnace 1270 is used to perform the heat treatment operation, as shown in FIG. 12C. The membrane 100 is placed on a suitable mount inside a crucible 1272 of the induction furnace 1270. A conductive coil 1274, such as a copper coil wraps around the crucible. The furnace is surrounded by a shield 1276 in some embodiments. An AC power supply 1278 applies alternating current to the conductive coil 1274. The electrical current flowing through the coil creates a rapidly reversing magnetic field that induces eddy currents in the membrane 100 that heat the membrane by joule heating. In some embodiments, the current from the power supply 1278 is adjusted such that the membrane is heated at a temperature in a range from about 1000° C. to about 3600° C. to cause amorphous carbon in the nanotubes and shells to crystallize and/or bond to each other, as described herein.

In some embodiments, a graphite furnace 1280, such as a graphite electrical resistance furnace, is used to perform the heat treatment operation, as shown in FIG. 12D. The membrane 100 is placed on a suitable mount 1288, such as graphite table, in the heating zone 1286 of the furnace. Graphite heaters 1284 are used to heat the furnace. The heat is produced by an electrical current provided by a power supply 1298 to the graphite heaters 1284. The furnace is surrounded by a heat shield 1290 in some embodiments. In some embodiments, insulation 1292, such as carbon fibers, surrounds the chamber 1282. In some embodiments, an inert gas, such as argon or nitrogen, is flowed through the chamber 1282 via gas inlet 1294 and gas outlet 1296 during the heat treatment. In some embodiments, the current from the power supply 1298 is adjusted such that the membrane is heated at a temperature in a range from about 1000° C. to about 3600° C. to cause amorphous carbon in the nanotubes and shells to crystallize and/or bond to each other, as described herein.

In some embodiments, the membrane support 1235 a frame-shaped material. In some embodiments, the membrane support 1235 is made of a material that is vaporized at the heat treatment temperatures, and is thus substantially removed from the membrane during the heat treatment operation. In other embodiments, the heat membrane support 1235 is made of one or more layers of graphite or an ultra-high temperature ceramic, such as HfCN, HfC, TaC, NbC, ZrC, HfN, HfB₂, ZrB₂, TiB₂, TiC, NbB₂, TaB₂, TiN, or ZrN. In some embodiments, the membrane support is the frame 15 of the pellicle 10. Because the membrane support in some embodiments can withstand the high heat treatment temperatures, the pellicle remains adhered to the membrane support after the heat treatment operation. In other embodiments, the main network membrane 100 is attached to the frame 15 as described herein in reference to FIGS. 6A and 6B, and 7A and 7B, after the heat treatment operation is performed.

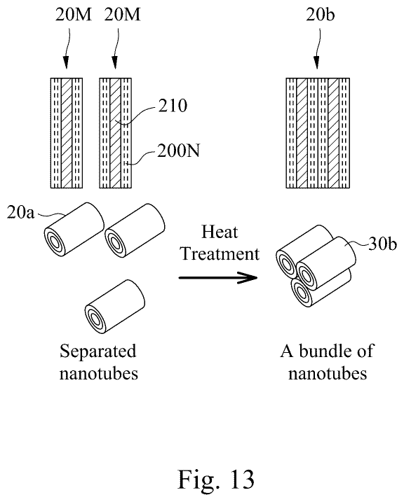

As shown in FIG. 13, in some embodiments, the heat treatment operation causes single separated nanotubes 20a (single-wall or multiwall nanotubes) to join and form a bundle of high-crystalline nanotubes 30b having a seamless graphitic structure, in which the nanotubes are firmly bonded or joined more than merely contacting each other. Two or more nanotubes 20a can be connected (bonded or joined) to form the bundle 30b of nanotubes. In some embodiments, 2-15 nanotubes are bonded to form a medium bundle. In some embodiments, 16-100 nanotubes are bonded to form a large bundle. In some embodiments, more than 100 nanotubes are bonded to form a very large bundle.

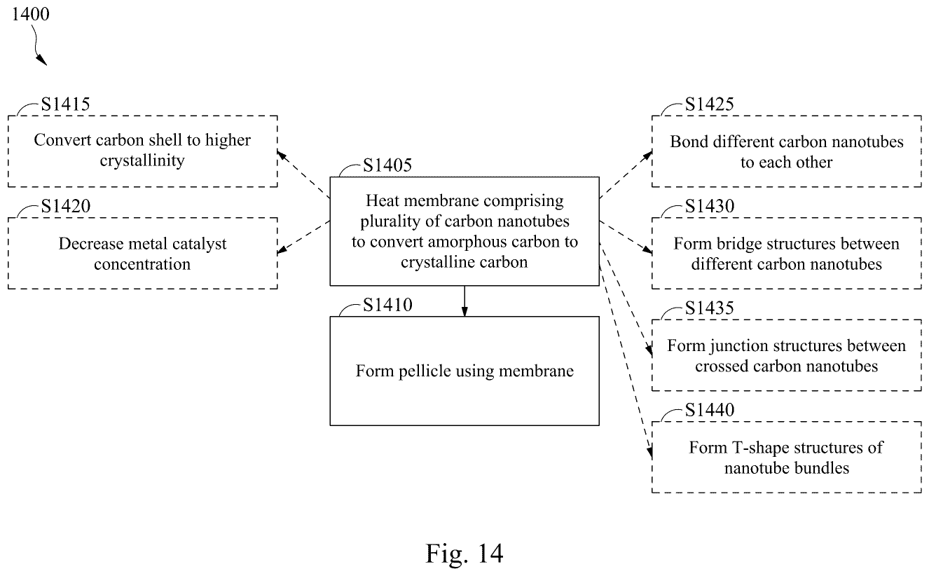

FIGS. 14-16 are flowcharts showing methods of manufacturing a pellicle according to embodiments of the present disclosure. It is understood that additional operations can be provided before, during, and after the processes shown in FIGS. 14-16 and some of the operations described below can be replaced or eliminated, for additional embodiments of the method. The order of the operations/processes may be interchangeable.

A method 1400 of manufacturing a pellicle 10 according to some embodiments of the disclosure is illustrated in the flow chart of FIG. 14. The method 1400 includes an operation S1405 of heating a membrane 100 including a plurality of carbon nanotubes 20a at a temperature sufficient to convert amorphous carbon to crystalline carbon. In some embodiments, the membrane 100 is heated in a chamber having an oxygen content less than air. A pellicle is formed in operation S1410 using the membrane 100 after the heating the membrane in operation S1405. In some embodiments, the membrane 100 includes a plurality of carbon shells 25a having a first level of crystallinity, and during the heating the membrane, the plurality of carbon shells 25a having the first level of crystallinity are converted to a plurality of carbon shells 25b having a second level of crystallinity in operation S1415, where the second level of crystallinity is greater than the first level of crystallinity. In some embodiments, the membrane includes a metal catalyst 45 at a first concentration, and during the heating the membrane operation S1405, the first concentration of the metal catalyst decreases to a second concentration in operation S1420. In some embodiments, the method 1400 includes an operation S1425 of bonding different carbon nanotubes to each other during the heating the membrane operation S1405. In some embodiments, the method 1400 includes an operation S1430 of forming bridge structures 35 between different carbon nanotubes 20b or nanotube bundles 30b during the heating the membrane operation S1405. In some embodiments, the method 1400 includes an operation S1435 of forming junction structures 40 between crossed carbon nanotubes 20b or nanotube bundles 30b during the heating the membrane operation S1405. In some embodiments, the method 1400 includes an operation S1440 of forming T-shape structures 50 of carbon nanotubes 20b or nanotube bundles 30b during the heating the membrane operation S1405.

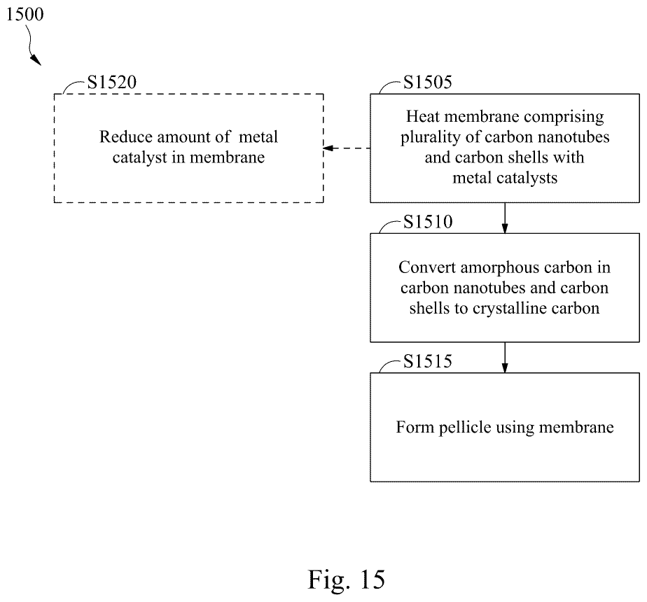

Another method 1500 of manufacturing a pellicle according to some embodiments of the disclosure is illustrated in the flow chart of FIG. 15. The method 1500 includes an operation S1505 of heating a membrane 100 including a plurality of carbon nanotubes 20a and carbon shells 25a with metal catalysts 45 in a chamber 1240 at a temperature ranging from 1000° C. to 3600° C. Amorphous carbon in the carbon nanotubes 20a and carbon shells 25a is converted to crystalline carbon in operation S1510. In operation S1515, a pellicle is formed using the membrane 100 after the heating the membrane operation S1505. In some embodiments, an amount of the metal catalysts 45 in the membrane 100 is reduced in operation S1520 during the heating the membrane operation S1505.

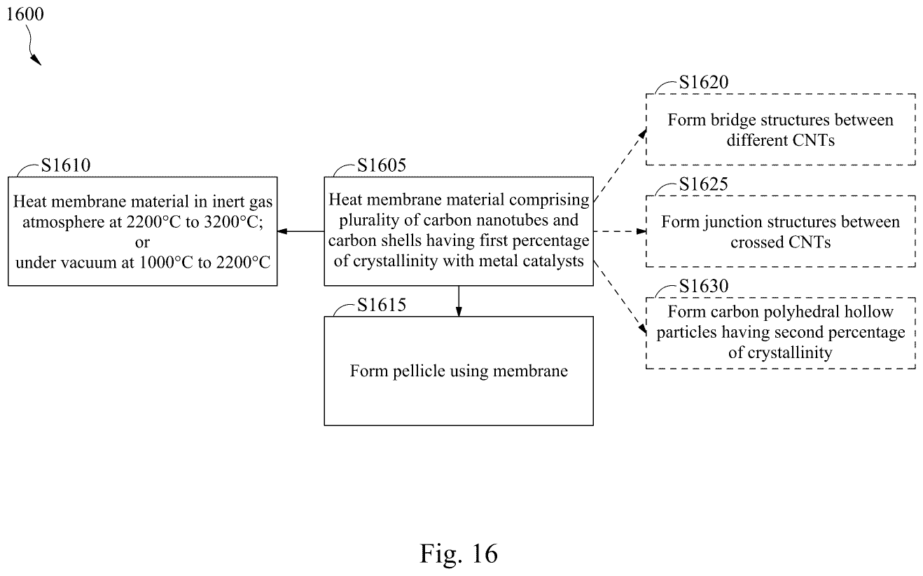

Another method 1600 of manufacturing a pellicle according to some embodiments of the disclosure is illustrated in FIG. 16. The method 1600 includes an operation S1605 of heating a membrane material including a plurality of carbon nanotubes (CNTs) 20a and carbon shells 25a having a first percentage of crystallinity with metal catalysts 45. The heating the membrane in operation S1605 includes an operation S1610 of heating the membrane material in an inert gas atmosphere having an oxygen concentration of no more than 10 ppm at a temperature ranging from about 2200° C. to about 3200° C., or heating the membrane material under a vacuum condition at a pressure of less than 10⁻⁵ Torr at a temperature ranging from about 1000° C. to about 2200° C. In operation S1615, an EUV pellicle 10 is formed with the heated membrane material. In some embodiments, the method 1600 includes an operation S1620 of forming bridge structures 35 between different CNTs 20b or nanotube bundles 30b during the heating the membrane material operation S1605. In some embodiments, the method 1600 includes an operation S1625 of forming junction structures 40 between crossed CNTs 20b or nanotube bundles 30b during the heating the membrane material operation S1605. In some embodiments, the method 1600 includes an operation S1630 of forming carbon polyhedral hollow particles 20b having a second percentage of crystallinity during the heating the membrane material operation S1605, wherein the second percentage of crystallinity is higher than the first percentage of crystallinity.

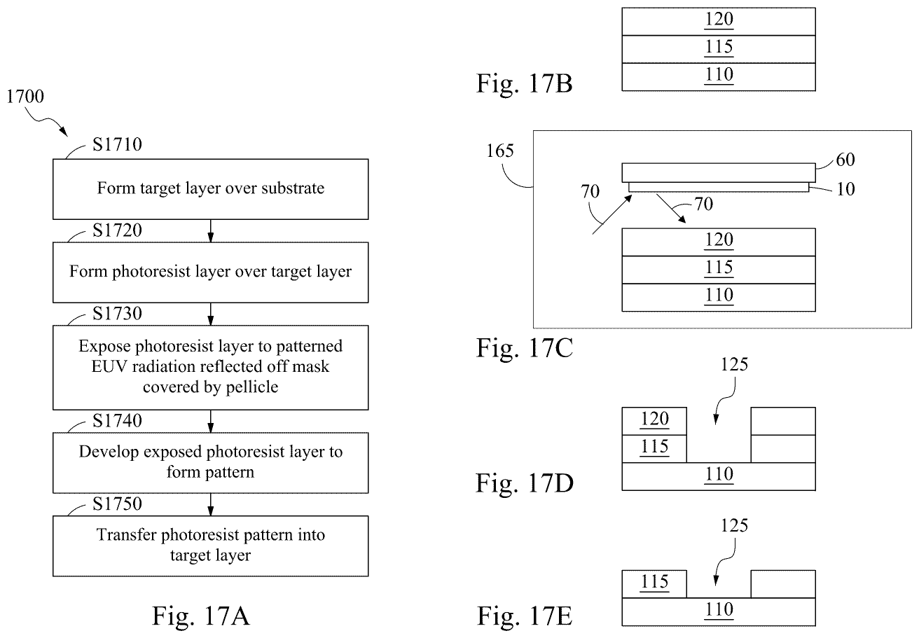

FIG. 17A shows a flowchart of a method 1700 of making a semiconductor device, and FIGS. 17B, 17C, 17D, and 17E show a sequential manufacturing method of making a semiconductor device in accordance with embodiments of present disclosure. A semiconductor substrate or other suitable substrate to be patterned to form an integrated circuit thereon is provided. In some embodiments, the semiconductor substrate includes silicon. Alternatively or additionally, the semiconductor substrate includes germanium, silicon germanium or other suitable semiconductor material, such as a Group III-V semiconductor material. At operation S1710 of FIG. 17A, a target layer 115 to be patterned is formed over the semiconductor substrate 110. In certain embodiments, the target layer 115 is the semiconductor substrate. In some embodiments, the target layer 115 includes a conductive layer, such as a metallic layer or a polysilicon layer; a dielectric layer, such as silicon oxide, silicon nitride, SiON, SiOC, SiOCN, SiCN, hafnium oxide, or aluminum oxide; or a semiconductor layer, such as an epitaxially formed semiconductor layer. In some embodiments, the target layer 115 is formed over an underlying structure, such as isolation structures, transistors or wirings. At S1720, a photoresist layer 120 is formed over the target layer, as shown in FIG. 17B. The photoresist layer 120 is sensitive to the radiation 70 from the exposure radiation source during a subsequent photolithography exposing operation. In the present embodiment, the photoresist layer 120 is sensitive to EUV light used in the photolithography exposing operation. The photoresist layer 120 may be formed over the target layer 115 by spin-on coating or other suitable technique. The coated photoresist layer may be further baked to drive out solvent in the photoresist layer. At operation S1730, the photoresist layer 120 is patterned in a photolithography exposure apparatus 165 by directing EUV radiation 70 toward a reflective photomask 60. A pellicle 10, as described herein, covers the photomask 60. The EUV radiation 70 is reflected off the photomask 60 and is directed towards the photoresist layer 120. During the photolithography exposing operation, an integrated circuit (IC) design pattern defined on the photomask 60 is imaged to the photoresist layer 120 to form a latent pattern thereon. The patterning of the photoresist layer further includes developing the exposed photoresist layer in operation S1740 to form a patterned photoresist layer having one or more openings 125. In one embodiment where the photoresist layer is a positive tone photoresist layer, the exposed portions of the photoresist layer are removed during the developing operation. In other embodiments, the photoresist layer is a negative tone photoresist layer and the unexposed portions of the photoresist layer are removed during the developing operation. The patterning of the photoresist layer may further include other operations, such as various baking operations at different stages. For example, a post-exposure-baking (PEB) process may be implemented after the photolithography exposure operation and before the developing operation.

At operation S1750, the pattern 125 in the photoresist layer is transferred to the target layer 115 using the patterned photoresist layer 120 as an etching mask, as shown in FIG. 17D. The portions of the target layer exposed within the openings of the patterned photoresist layer are etched while the remaining portions are protected from etching. Further, the patterned photoresist layer may be removed by wet stripping or plasma ashing, as shown in FIG. 17E.

Other embodiments include other operations before, during, or after the operations described above. In some embodiments, the disclosed methods include forming fin field effect transistor (FinFET) structures. In some embodiments, a plurality of active fins are formed on the semiconductor substrate. Such embodiments, further include etching the substrate through the openings of a patterned hard mask to form trenches in the substrate; filling the trenches with a dielectric material; performing a chemical mechanical polishing (CMP) process to form shallow trench isolation (STI) features; and epitaxy growing or recessing the STI features to form fin-like active regions. In some embodiments, one or more gate electrodes are formed on the substrate. Some embodiments include forming gate spacers, doped source/drain regions, contacts for gate/source/drain features, etc. In other embodiments, a target pattern is formed as metal lines in a multilayer interconnection structure. For example, the metal lines may be formed in an inter-layer dielectric (ILD) layer of the substrate, which has been etched to form a plurality of trenches. The trenches may be filled with a conductive material, such as a metal; and the conductive material may be polished using a process such as chemical mechanical planarization (CMP) to expose the patterned ILD layer, thereby forming the metal lines in the ILD layer. The above are non-limiting examples of devices/structures that can be made and/or improved using the method described herein.

In some embodiments, active components such diodes, field-effect transistors (FETs), metal-oxide semiconductor field effect transistors (MOSFET), complementary metal-oxide semiconductor (CMOS) transistors, bipolar transistors, high voltage transistors, high frequency transistors, sheet FETs, FinFETs, gate all around FETs (GAA FETs), other three-dimensional (3D) FETs, other memory cells, and combinations thereof are formed, according to embodiments of the disclosure.

Methods of the present disclosure: (1) remove impurities, such as metal particles, including transition metal particles, that reduce EUV transmittance, (2) transform amorphous carbon to crystalline carbon, such as graphite or graphene, which improves EUV transmittance (3) increase mechanical strength and chemical stability of the pellicle to provide longer operating lifetime in the demanding EUV exposure environment, and (4) fix the pore size of the pellicle by cross-connected CNTs, which improves particle impenetrability.

The high temperature treatment according to embodiments of the disclosure simultaneously removes impurities, and transforms amorphous carbon to crystalline carbon, thereby increasing the crystallinity and EUV transmittance of the main network membrane. Embodiments of the present disclosure provide high transmittance and high strength EUV pellicles, and low particle penetrability of the main network membrane, thereby improving the manufacturing efficiency of semiconductor devices.

An embodiment of the disclosure is a method of manufacturing a pellicle, including heating a membrane including a plurality of carbon nanotubes at a temperature sufficient to convert amorphous carbon to crystalline carbon. The membrane is heated in a chamber having an oxygen content less than air. A pellicle is formed and includes the membrane after the heating the membrane. In an embodiment, the membrane includes a plurality of carbon shells having a first level of crystallinity, and during the heating the membrane, the plurality of carbon shells having the first level of crystallinity are converted to a plurality of carbon shells having a second level of crystallinity, where the second level of crystallinity is greater than the first level of crystallinity. In an embodiment, the membrane includes a metal catalyst at a first concentration, and during the heating the membrane, the first concentration of the metal catalyst decreases to a second concentration. In an embodiment, the membrane is heated at a temperature ranging from 2200° C. to 3200° C. In an embodiment, an oxygen concentration in the chamber is no more than 10 ppm during the heating. In an embodiment, the membrane is heated at a temperature ranging from 1000° C. to 2200° C. In an embodiment, a pressure in the chamber is less than 10⁻⁵ Torr during the heating. In an embodiment, the method includes bonding different carbon nanotubes to each other during the heating the membrane. In an embodiment, the method includes forming bridge structures between different carbon nanotubes during the heating the membrane. In an embodiment, the method includes forming junction structures between crossed carbon nanotubes or forming T-shape structures from a plurality of carbon nanotubes or nanotube bundles during the heating the membrane.

Another embodiment of the disclosure is a method of manufacturing a pellicle including heating a membrane including a plurality of carbon nanotubes and carbon shells with metal catalysts in a chamber at a temperature ranging from 1000° C. to 3600° C. Amorphous carbon in the carbon nanotubes and carbon shells is converted to crystalline carbon. A pellicle is formed and includes the membrane after the heating the membrane. In an embodiment, the temperature ranges from 1000° C. to 3200° C. In an embodiment, an oxygen concentration in the chamber during the heating the membrane is no more than 10 ppm. In an embodiment, a pressure in the chamber during the heating the membrane is less than 10⁻⁵ Torr. In an embodiment, an amount of metal catalysts in the membrane is reduced during the heating the membrane. In an embodiment, the metal catalysts include Fe.

Another embodiment of the disclosure is a method of manufacturing a pellicle including heating a membrane material including a plurality of carbon nanotubes (CNTs) and carbon shells having a first percentage of crystallinity with metal catalysts. The heating the membrane includes: heating the membrane material in an inert gas atmosphere having an oxygen concentration of no more than 0.2 ppm at a temperature ranging from 2200° C. to 3200° C., or heating the membrane material under a vacuum condition at a pressure of less than 10⁻⁵ Torr at a temperature ranging from 1000° C. to 2200° C. An EUV pellicle is formed and includes the membrane material after heating. In an embodiment, the method includes forming bridge structures between different CNTs during the heating the membrane material. In an embodiment, the method includes forming junction structures between crossed CNTs during the heating the membrane material. In an embodiment, the method includes forming carbon polyhedral hollow particles having a second percentage of crystallinity during the heating the membrane material, wherein the second percentage of crystallinity is higher than the first percentage of crystallinity.

Another embodiment of the disclosure is a pellicle including a membrane disposed over a frame. The membrane includes a plurality of crystalline carbon nanotubes and a plurality of carbon polyhedral hollow particles. In an embodiment, the membrane has a thickness ranging from 10 to 100 nm. In an embodiment, at least one of the crystalline carbon nanotubes has an interior diameter ranging from 0.5 nm to 10 nm. In an embodiment, at least one of the crystalline carbon nanotubes includes a plurality of coaxial walls. In an embodiment, bridge structures are connected to adjacent crystalline carbon nanotubes. In an embodiment, adjacent crossing crystalline carbon nanotubes are joined at a junction structure. In an embodiment, at least one of the crystalline carbon nanotubes is bent at angle ranging from 10° to 170°. In an embodiment, the angle ranges from 30° to 150°. In an embodiment, the plurality of crystalline carbon nanotubes include bundles of crystalline carbon nanotubes joined together. In an embodiment, the carbon polyhedral hollow particles are composed of flat planes having a graphite two-dimensional structure. In an embodiment, an angle between two adjacent flat planes ranges from 80° to 160°. In an embodiment, a ratio of an intensity of a D-band to an intensity of a G-band in Raman spectroscopy (I_{D}/I_{G}) of the membrane is ≤0.1. In an embodiment, I_{D}/I_{G} is ≤0.05. In an embodiment, I_{D}/I_{G} is ≤0.02.

Another embodiment of the disclosure is a pellicle including a membrane disposed over a frame. The frame is made of an inorganic material, and the membrane includes a plurality of crystalline carbon nanotube bundles and a plurality of carbon polyhedral hollow particles. The crystalline carbon nanotube bundles include at least two or more adjacent crystalline carbon nanotubes joined together along a length of the crystalline nanotube bundles, and adjacent crystalline carbon nanotube bundles are connected to each other by a crystalline carbon nanotube bridge structure. In an embodiment, the frame is formed of at least one layer of a crystalline silicon, a polysilicon, a silicon oxide, a silicon nitride, an aluminum oxide, or a ceramic material. In an embodiment, the membrane has a thickness ranging from 10 to 100 nm. In an embodiment, a ratio of an intensity of a D-band to an intensity of a G-band in Raman spectroscopy (I_{D}/I_{G}) of the membrane is ≤0.1.

Another embodiment of the disclosure includes a pellicle including a membrane disposed over a frame, wherein the frame is made of an inorganic material. The membrane includes a plurality of crystalline carbon nanotubes, a plurality of crystalline carbon nanotube bundles, and a plurality of crystalline carbon polyhedral hollow particles. The crystalline carbon nanotube bundles include at least two or more adjacent crystalline carbon nanotubes joined together along a length of the crystalline carbon nanotube bundles. Adjacent crystalline carbon nanotube bundles are connected to each other by at least one of the plurality of crystalline carbon nanotubes. At least two adjacent crystalline carbon nanotubes are joined together at a first junction structure, and at least two adjacent crystalline bundles are joined together at a second junction structure. In an embodiment, a ratio of an intensity of a D-band to intensity of a G-band in Raman spectroscopy (I_{D}/I_{G}) of the membrane is ≤0.1.

It will be understood that not all advantages have been necessarily discussed herein, no particular advantage is required for all embodiments or examples, and other embodiments or examples may offer different advantages.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a pellicle, comprising:
heating a membrane comprising a plurality of carbon nanotubes at a temperature sufficient to convert amorphous carbon to crystalline carbon,
wherein the membrane is heated in a chamber having an oxygen content less than air; and
forming a pellicle including the membrane after the heating the membrane.

2. The method according to claim 1, wherein the membrane further comprises a plurality of carbon shells having a first level of crystallinity, and during the heating the membrane, the plurality of carbon shells having the first level of crystallinity are converted to a plurality of carbon shells having a second level of crystallinity, where the second level of crystallinity is greater than the first level of crystallinity.

3. The method according to claim 1, wherein the membrane further comprises a metal catalyst at a first concentration, and during the heating the membrane the first concentration of the metal catalyst decreases to a second concentration.

4. The method according to claim 1, wherein the membrane is heated at a temperature ranging from 2200° C. to 3200° C.

5. The method according to claim 4, wherein an oxygen concentration in the chamber is no more than 10 ppm during the heating.

6. The method according to claim 1, wherein the membrane is heated at a temperature ranging from 1000° C. to 2200° C.

7. The method according to claim 6, wherein a pressure in the chamber is less than 10⁻⁵ Torr during the heating.

8. The method according to claim 1, further comprising bonding different carbon nanotubes to each other during the heating the membrane.

9. The method according to claim 1, further comprising forming bridge structures between different carbon nanotubes during the heating the membrane.

10. The method according to claim 1, further comprising forming junction structures between crossed carbon nanotubes or forming T-shape structures from a plurality of carbon nanotubes or nanotube bundles during the heating the membrane.

11. A method of manufacturing a pellicle, comprising:
heating a membrane comprising a plurality of carbon nanotubes and carbon shells with metal catalysts in a chamber at a temperature ranging from 1000° C. to 3600° C.;
converting amorphous carbon in the carbon nanotubes and carbon shells to crystalline carbon; and
forming a pellicle including the membrane after the heating the membrane.

12. The method according to claim 11, wherein the temperature ranges from 1000° C. to 3200° C.

13. The method according to claim 11, wherein an oxygen concentration in the chamber during the heating the membrane is no more than 10 ppm.

14. The method according to claim 11, wherein a pressure in the chamber during the heating the membrane is less than 10⁻⁵ Torr.

15. The method according to claim 11, further comprising reducing an amount of the metal catalysts in the membrane during the heating the membrane.

16. The method according to claim 11, wherein the metal catalysts include Fe.

17. A pellicle, comprising:
a membrane disposed over a frame,
wherein the membrane includes a plurality of crystalline carbon nanotubes and a plurality of carbon polyhedral hollow particles.

18. The pellicle of claim 17, wherein the membrane has a thickness ranging from 10 to nm.

19. The pellicle of claim 17, wherein at least one of the crystalline carbon nanotubes has an interior diameter ranging from 0.5 nm to 10 nm.

20. The pellicle of claim 17, wherein at least one of the crystalline carbon nanotubes includes a plurality of coaxial walls.
